(19) United States
(12) Patent Application Publication
(10) Pub. No.: US 2006/0177690 A1
(43) Pub. Date: Aug. 10, 2006

(54) Tri-layer PLED devices with both room-temperature and high-temperature operational stability

(75) Inventor: Wencheng Su, San Jose, CA (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Osram Opto Semiconductors GmbH & Co. OHG

(21) Appl. No.: 11/052,942

(22) Filed: Feb. 7, 2005

(51) Int. Cl. H01L 51/50; H01L 51/56; H05B 33/12

(52) U.S. Cl. 428/690; 428/917; 313/504; 313/506; 427/66

(57) ABSTRACT

An electroluminescent device has a hole injection layer fabricated using a conducting polymer with acid dopant in which acidic hydrogen ions are replaced with selected organic and inorganic other ions. The device has a three layer organic stack, including an emissive layer and a hole transporting interlayer which is rendered insoluble to the solvent used for fabricating the emissive layer through crosslinking or polarity adjustment.

### BACKGROUND

1. Field of the Invention

In general, the invention involves organic light emitting diode (OLED) devices. More specifically, the invention involves a tri-layer OLED devices with both room-temperature and high temperature operational stability.

2. Related Art

An OLED device could be fabricated from small molecule or polymeric materials. A typical device structure of a polymer light-emitting diode (PLED) consists of an anode (e.g. indium-tin-oxide (ITO)), a hole injection layer (e.g. PEDOT:PSS or polyaniline), an electroluminescent layer, and a cathode layer (e.g. barium covered with aluminum). Among the two organic layers, the function of the hole injection layer is to provide efficient hole injection into subsequent layers. In addition, hole injection layer also acts as a buffer layer to smooth the surface of the anode and to provide a better adhesion for the subsequent layer. The function of the electroluminescent layer is to transport both types of carriers and to efficiently produce light of desirable wavelength from electron-hole pair (exciton) recombination. Relatively low operational lifetimes of polymer light-emitting diodes (PLEDs) are a serious problem on the way to wide-scale commercialization of organic electroluminescent devices. Many factors are responsible for limited operational lifetime of such devices, some of which, but not all, include degradation of injecting electrodes, degradation of light-emitting properties of the emitting material, deterioration of charge transporting properties of materials, that constitute a device, and many others.

To improve the operational lifetimes of PLED devices, various approaches have been explored, for instance, using improved encapsulation method, modifying the property of the emissive materials, modifying the device structure, etc. Among them, insertion of well-defined hole transporting interlayer between the hole injection layer and the emissive layer can significantly improve the room temperature lifetimes of polymer light-emitting diodes. The function of the well-defined hole transporting interlayer includes transporting holes, blocking electrons, and moving the recombination zone away from the interface.

The performance requirement for electroluminescent devices is usually determined by the intended applications. For most applications, e.g. portable electronics, only room temperature lifetime performance is a major concern. However, for applications like automotive displays, not only sufficient room temperature lifetime is required, but also lifetime of more than 1000 hr at 85° C. usually has to be demonstrated. The tri-layer PLEDs we developed before was found to increase room temperature lifetime performance, but their lifetime at 85° C. is short and insufficient for automotive applications.

### BRIEF DESCRIPTION OF THE DRAWINGS

FIG. 1 shows a cross-sectional view of an embodiment of an electroluminescent device 405 according to at least one embodiment of the invention.

FIG. 2 illustrates lifetime performance at room temperature of PLED devices with and without ion replacement.

FIG. 3 illustrates lifetime performance at high temperature of PLED devices with and without ion replacement.

FIG. 4 illustrates the lifetime performance difference between two layer organic stack PLED devices and three layer organic stack PLED devices even when ion replacement is performed in each.

### DETAILED DESCRIPTION

In at least one embodiment of the invention, an electroluminescent (EL) device structure with a triple layer organic stack is disclosed which combines 1) the use of a hole transporting (HT) interlayer which is rendered or selected to be insoluble to the solvent used to fabricate the emissive layer; 2) a hole injection layer (HIL) which is modified by ion replacement; and 3) an emissive layer of particular thickness. The HT interlayer can be rendered insoluble by the use of cross-linking so that it does not degrade by the solvent used to fabricate the emissive layer. The term “degrade” as used herein means significant physical and/or chemical change has occurred, e.g., dissolving, intermixing, delaminating, etc. A least a portion of available H⁺ ions in the acid used in fabricating the HIL can be replaced by organic or inorganic positive ions.

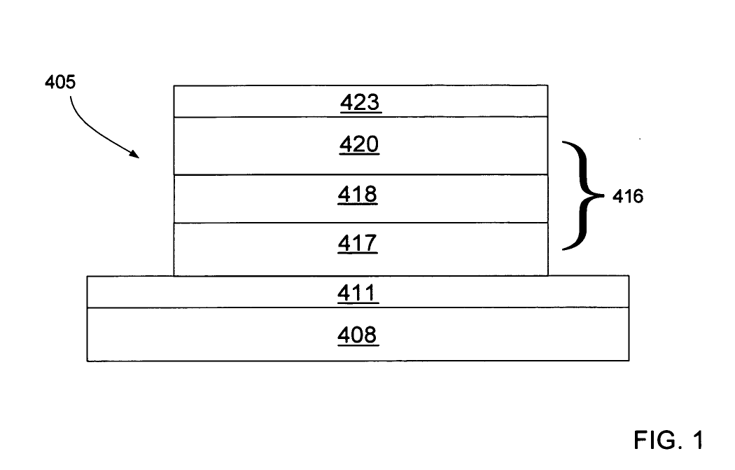

FIG. 1 shows a cross-sectional view of an embodiment of an EL device 405 according to at least one embodiment of the invention. The EL device 405 may represent one pixel or sub-pixel of a larger display. As shown in FIG. 1, the EL device 405 includes a first electrode 411 on a substrate 408. As used within the specification and the claims, the term “on” includes when layers are in physical contact or when layers are separated by one or more intervening layers. The first electrode 411 may be patterned for pixilated applications or remain un-patterned for backlight applications.

One or more organic materials are deposited to form one or more organic layers of an organic stack 416. The organic stack 416 is on the first electrode 411. In at least one embodiment of the invention, the organic stack 416 includes a hole injection layer (“HIL”) 417 and emissive layer (EML) 420 and a hole transporting (HT) interlayer 418 disposed between the HIL 417 and the EML layer 420. If the first electrode 411 is an anode, then the HIL 417 is on the first electrode 411. Alternatively, if the first electrode 411 is a cathode, then the EML 420 is on the first electrode 411, and the HIL 417 is on the EML 420. The OLED device 405 also includes a second electrode 423 on the organic stack 416. Other layers than that shown in FIG. 1 may also be added including barrier, charge transport/injection, and interface layers between or among any of the existing layers as desired. Some of these layers, in accordance with the invention, are described in greater detail below.

Substrate 408

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of an active-matrix OLED device. A single substrate 408 is typically used to construct a larger display containing many pixels (EL devices) such as EL device 405 repetitively fabricated and arranged in some specific pattern.

First Electrode 411:

In one configuration, the first electrode 411 functions as an anode (the anode is a conductive layer which serves as a hole-injecting layer and which comprises a material with work function typically greater than about 4.5 eV). Typical anode materials include metals (such as platinum, gold, palladium, and the like); metal oxides (such as lead oxide, tin oxide, ITO (Indium Tin Oxide), and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 can be from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

HIL 417:

The HIL 417 has good hole conducting properties and is used to effectively inject holes from the first electrode 411 to the EML 420 (via the HT interlayer 418, see below). The hole injection layer usually consists of a conductive polymer with a polymeric acid dopant. Examples of conductive polymers include polypyrrole, polythiophene, polyaniline, etc. For example, the HIL 417 can be fabricated from conducting polyaniline (“PANI”), or PEDOT:PSS (a solution of poly(3,4-ethylenedioxythiophene) (“PEDOT”) and polystyrenesulfonic acid (“PSS”) available as Baytron P from HC Starck). The HIL 417 can have a thickness from about 5 nm to about 1000 nm, and is conventionally used from about 50 nm to about 250 nm. Preferably, in accordance with at least one embodiment of the invention, the thickness of the HIL is about between 60 nm and 200 nm and consists of ion-replaced modified PEDOT:PSS, as discussed below. The HIL 417 can be formed using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. A hole injecting and/or buffer material is deposited on the first electrode 411 and then allowed to dry into a film. The dried film represents the HIL 417. In accordance with the invention, the HIL 417 is modified by ion replacement. For instance, in at least one embodiment of the invention, conventionally available PEDOT:PSS solution is modified by replacing, at a particular concentration, the H⁺ ions in the PSS with one or more different organic and/or inorganic positive ions. The ion replacement can be achieved by replacing at least some of the H⁺ ions in the acid with an inorganic material such as an alkali or earth alkali metal ion (e.g. Li, Na, Mg, K, Ca, Rb, Sr, Cs, Ba). Alternatively, at least some of the H⁺ ions can be replaced with organic positive ions (e.g., N(CH₃)₄⁺, N(C₂H₅)₄)⁺). The degree of replacement of the acid H⁺ ions can be varied from 1-100%, preferably from 20-90%. The replacement of the at least some of the H⁺ ions in the acid can be realized through methods such as neutralization, ion exchange, etc. Combining ion replaced HIL materials with the tri-layer device structure described in this invention, significant benefits can be obtained, which include but not limited to:

1) It has little or no negative effect on room-temperature device performance such as device efficiency and lifetime;

2) It dramatically improves high temperature (e.g. 85° C.) device lifetime performance; and

3) It reduces lifetime dependence on HIL layer thickness, providing a lot of flexibility for device design.

Among the inorganic materials whose positive ions which can be used to replace the H⁺ ions in the acid are, for example, Li, Na, Mg, K, Ca, Rb, Sr, Cs, Ba, Al, Mn, Fe, Co, Ni, Cu and Zn. Among the organic materials that can be used to replace the H⁺ ions in the acid composing the HIL are: NH₄⁺, N(CH₃)₄⁺, N(C₂H₅)₄)⁺, N(C₃H₈)₄)⁺, N(C₃H₅)₈)⁺, CH₃NH₃⁺, CH₂CH₂NH₃⁺, CH₂CH₂CH₂NH₃⁺, CH₂CH₂CH₂CH₂NH₃⁺, (CH₃)₂NH₂⁺, (CH₃CH₂)₂NH₂⁺, (CH₃CH₂CH₂)₂NH₂⁺, (CH₃)₃NH⁺, (CH₃CH₂)₃NH⁺, (CH₃CH₂CH2)₃NH⁺, and so on.

In accordance with at least one embodiment of the invention, the H⁺ ions of PSS (polystyrene sulfonic acid) in a PEDOT:PSS mixture is replaced with sodium (Na) ions, with a thickness of the HIL layer at about 200 nm.

HT interlayer 418

The functions of the HT interlayer 418 are among the following: to assist injection of holes into the EML 420, reduce exciton quenching at the anode, provide better hole transport than electron transport, and block electrons from getting into the HIL 417 and degrading it. Some materials may have one or two of the desired properties listed, but the effectiveness of the material as an interlayer is believed to improve with the number of these properties exhibited. The HT interlayer 418 may consist at least partially of or may derive from one or more following compounds, their derivatives, moieties, etc: polyfluorene derivatives, poly(2,7-(9,9-di-n-octylfluorene)-(1,4-phenylene-((4-secbutylphenyl)imino)-1,4-phenylene) and derivatives which include cross-linkable forms, non-emitting forms of poly(p-phenylenevinylene), triarylamine type material (e.g. triphenyldiamine (TPD), α-napthylphenyl-biphenyl (NPB)) mixed with a crosslinkable small molecule or polymer matrix, thiopene, oxetane-functionalized polymers and small molecules etc. The hole transporting materials used in the HT interlayer 418 are preferably polymer hole transporting materials, but can be small molecule hole transporting materials with a polymer binder. For example, polymers containing aromatic amine groups in the main chain or side chains are widely used as hole transporting materials. Preferably, the thickness for such a well-defined hole transporting materials is 10-150 nm. More preferably the thickness for such a well-defined hole transport materials is 20-60 nm. In some embodiments of the invention, the HT interlayer 418 is fabricated using a cross-linkable hole transporting polymer. Examples of cross-linking chemistry can be found readily, for instance, as shown in U.S. Pat. No. 6,169,163 issued to Woo et al.

In accordance with at least one embodiment of the invention, the HT interlayer 418 is cross-linked or otherwise physically or chemically rendered insoluble to prevent degradation of the HT interlayer 418 when exposed to the solvent used in fabrication of subsequent layers such as the EML 420 (see below). Cross-linking can be achieved by exposing the film or deposited solution of HT interlayer 418 to light, ultraviolet radiation, heat, or by chemical process. This may include the use of ultraviolet curable inks, crosslinkable side chains, monomers which can be cross-linked into polymers, cross-linking agents, initiators, polymer blends, polymer matrices and so on. The general process(s) of cross-linking organic materials is well-known, and will not be described further. As one possible alternative to cross-linking, the HT interlayer 418 can be rendered insoluble by adjusting its polarity in accordance with the polarity of the solvent (e.g. toluene, xylene etc.) that is to be used in fabricating the EML 420. The HT interlayer 418 can be fabricated prior to or in conjunction with the cross-linking process by ink-jet printing, by spin-coating or other proper deposition techniques.

EML 420:

For organic LEDs (OLEDs), the EML 420 contains at least one organic material that emits light. These organic light emitting materials generally fall into two categories: small-molecule light emitting materials and polymer light-emitting materials. In embodiments of the invention, devices utilizing polymeric active electronic materials in EML 420 are especially preferred. The polymers may be organic or organo-metallic in nature. As used herein, the term organic also includes organo-metallic materials. Light-emission in these materials may be generated as a result of fluorescence or phosphorescence.

Preferably, these polymers are solvated in an organic solvent, such as toluene or xylene, and spun (spin-coated) onto the device, although other deposition methods are possible too.

The light emitting organic polymers in the EML 420 can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, organic polymers can be, for example: polyfluorenes; poly-p-phenylenevinylenes that emit white, red, blue, yellow, or green light and are 2-, or 2,5-substituted poly-p-phenylenevinylenes; polyspiro polymers.

In addition to polymers, smaller organic molecules that emit by fluorescence or by phosphorescence can serve as a light emitting material residing in EML 420. Combinations of PLED materials and smaller organic molecules can also serve as active electronic layer. For example, a PLED may be chemically derivatized with a small organic molecule or simply mixed with a small organic molecule to form EML 420. Examples of electroluminescent small molecule materials include tris(8-hydroxyquinolate) aluminum (Alq₃), anthracene, rubrene, tris(2-phenylpyridine) iridium (Ir(ppy)₃), triazine, any metal-chelate compounds and derivatives of any of these materials. Those materials can be applied by solutions methods or other proper methods.

In addition to materials that emit light, EML 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, triphenylamine, and triphenyldiamine. EML 420 may also include semiconductors, such as silicon, gallium arsenide, cadmium selenide, or cadmium sulfide.

All of the organic layers such as HIL 417, HT interlayer 418 and EML 420 can be ink-jet printed by depositing an organic solution or by spin-coating, or other deposition techniques. This organic solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops.

For instance, the HT interlayer 418 can be fabricated by depositing this solution, using either a selective or non-selective deposition technique, onto HIL 417. Further, any or all of the layers 417, 418 and 420 may be cross-linked or otherwise physically or chemically hardened as desired for stability and maintenance of certain surface properties desirable for deposition of subsequent layers.

Second Electrode (423)

In one embodiment, second electrode 423 functions as a cathode when an electric potential is applied across the first electrode 411 and the second electrode 423. In this embodiment, when an electric potential is applied across the first electrode 411, which serves as the anode, and second electrode 423, which serves as the cathode, photons are released from EML 420 and pass through first electrode 411 and substrate 408.

While many materials, which can function as a cathode, are known to those of skill in the art, most preferably a composition that includes aluminum, indium, silver, gold, magnesium, calcium, lithium fluoride, cesium fluoride, sodium fluoride, and barium, or combinations thereof, or alloys thereof, is utilized. Aluminum, aluminum alloys, and combinations of magnesium and silver or their alloys can also be utilized. In some embodiments of the invention, a second electrode 423 is fabricated by thermally evaporating in a two layer or combined fashion barium and aluminum in various amounts.

Preferably, the total thickness of second electrode 423 is from about 3 to about 1000 nanometers (nm), more preferably from about 50 to about 500 nm, and most preferably from about 100 to about 300 nm. While many methods are known to those of ordinary skill in the art by which the second electrode material may be deposited, vacuum deposition methods, such as physical vapor deposition (PVD) are preferred.

Often other steps such as washing and neutralization of films, addition of masks and photo-resists may precede cathode deposition. However, these are not specifically enumerated as they do not relate specifically to the novel aspects of the invention. Other steps (not shown) like adding metal lines to connect the anode lines to power sources may also be included in the workflow. Other layers (not shown) such as a barrier layer and/or getter layer and/or other encapsulation scheme may also be used to protect the electronic device. Such other processing steps and layers are well-known in the art and are not specifically discussed herein.

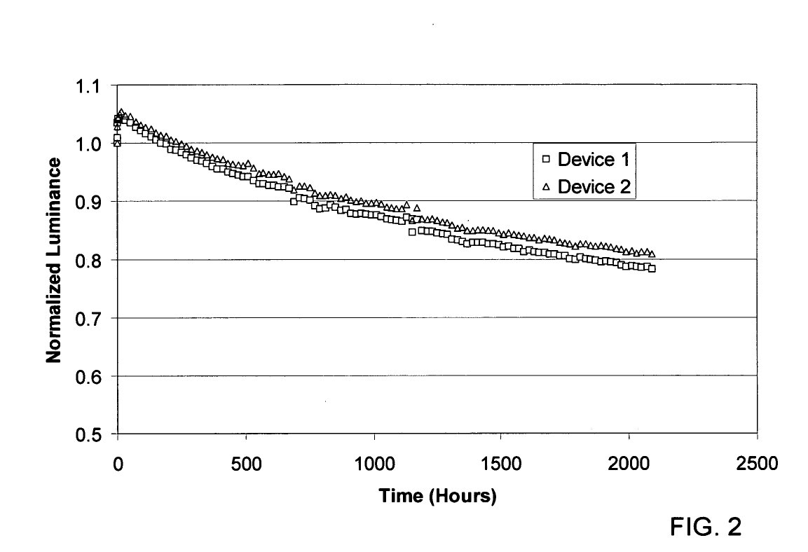

FIG. 2 illustrates lifetime performance at room temperature of PLED devices with and without ion replacement. A first device, labeled Device 1 has the following structure: Anode: ITO (Indium Tin Oxide)/HIL: 200 nm PEDOT:PSS/HT interlayer: 30 nm cross-linked/EML: 75 nm Green LEP and Cathode: 6 nm barium and 200 nm aluminum. The PEDOT:PSS used in the HIL has a PEDOT:PSS ratio of 1:20 and naturally contains about 250 ppm Na and 2300 ppm H⁺ ions. The HIL is coated on pretreated ITO coated glass substrates by spin-coating and has a thickness of about 200 nm. The well-defined hole transporting interlayer (HT) is fabricated from crosslinkable polymeric hole transporting materials spin-coated directly on the top of HIL. After processing, it becomes fully crosslinked and insoluble to the EML solvent. In this example, the deposited HT interlayer thickness is about 30 nm. For the EML, a green light-emitting polymer is then spin-coated on the top of the well-defined HT interlayer and has a thickness of about 75 nm. The cathode is subsequently deposited on the top of the LEP through thermal evaporation technique. The device is further encapsulated with a glass cover lid and epoxy.

A second device, labeled Device 2, has an identical structure and processing history except that some (approximately 41%) of the H⁺ ions in the HIL were replaced with sodium ions. The ion replacement in the HIL was achieved by neutralizing the PEDOT:PSS solution used to fabricate the HIL. The H⁺ ions in the PEDOT:PSS solution were neutralized by adding NaOH solution such that the total amount of sodium ions in solution is about 1200 ppm. This led to about 41% of the acid H⁺ ions being replaced by Na ions. In this case, for instance, 2.12 gram 10% NaOH is added to 100 gram PEDOT:PSS solution to form the ion-replaced HIL.

The lifetime testing was performed at room temperature under a multiplexed driving scheme with a duty cycle of 1/64 (mux 64) and frame rate of 100 Hz. The devices were driven at constant current and at initial luminance of 250 nits at room temperature. As shown in FIG. 2, at room temperature, replacement of the PEDOT acid H⁺ ions with sodium ions does not show negative effect on the lifetime performance of green PLED devices having a three layer organic stack (HIL/HTL/EML).

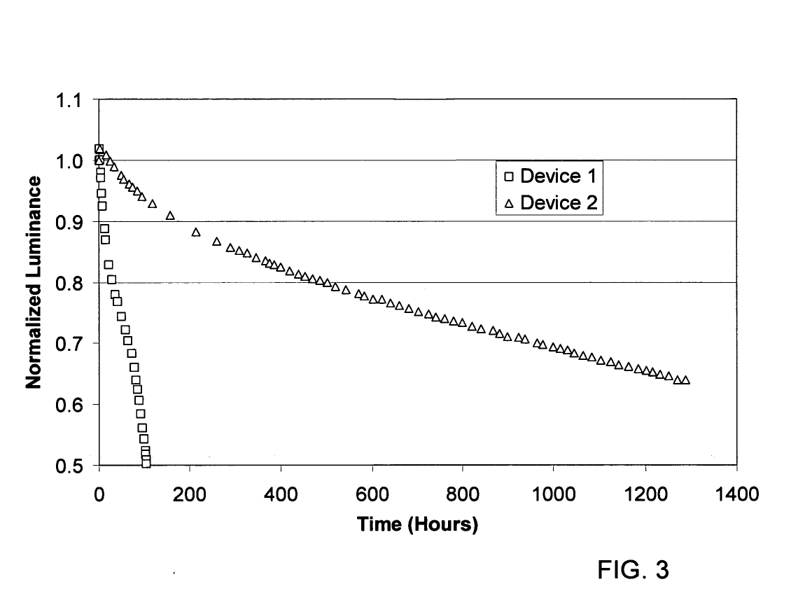

FIG. 3 illustrates lifetime performance at high temperature of the PLED devices with and without ion replacement. Devices with identical composition to that described above, Device 1 and Device 2, were tested under a multiplexed driving scheme with a duty cycle of 1/64 (mux 64) and frame rate of 100 Hz. The devices were driven at constant current and at initial luminance of 220 nits at 85° C. At 85° C., replacement of the PEDOT:PSS acid H⁺ ions with Na⁺ ions results in significant improvement in device lifetime. More than ten times improvement in lifetime is seen for devices with ion replaced HIL. At 85° C., the projected lifetime for tri-layer green PLED devices with ion-replaced HILs is greater than 1500 hours under mux 64 operation at 220 nits initial luminance. This is a practical lifetime for automotive applications. On the contrary, the green PLED devices (three layer organic stack) with unmodified HIL only show about 100 hours lifetime at 85° C. Similar results were obtained for orange-emitting three-layer organic stack PLED devices where room temperature lifetime was not adversely affected and lifetime performance at high temperature (85° C.) was dramatically improved when some of the H⁺ ions in the HIL were replaced with Na⁺ ions.

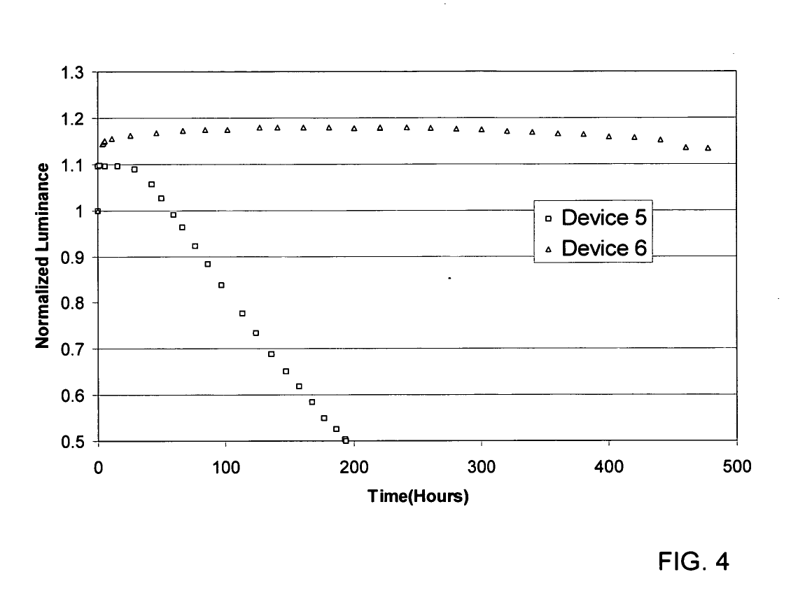

FIG. 4 illustrates the lifetime performance difference between two layer organic stack PLED devices and three layer organic stack PLED devices even when ion replacement is performed in each. A first device, labeled Device 5 has a two layer organic stack and the following structure: Anode: ITO/HIL: 60 nm ion-replaced PEDOT:PSS/EML: 75 nm orange LEP/Cathode: 6 nm barium and 200 nm aluminum. The PEDOT:PSS solution prior to ion replacement had a PEDOT:PSS ratio of 1:20 and naturally contains about 250 ppm Na and about 2300 ppm H⁺ ions. The PEDOT H⁺ ions are neutralized through added NaOH solution such that the total amount of sodium in solution is about 1500 ppm. This equates to about 54% of the acid H⁺ ions being replaced by Na⁺ ions (for instance, to achieve this, 2.65 gram of 10% NaOH is added to 97.35 gram PEDOT:PSS solution). The HIL is spin-coated on pretreated ITO-coated glass substrates and has a thickness of about 60 nm. An orange light-emitting polymer (LEP) is then spin-coated on the top of the HIL and has a thickness of about 75 nm. The cathode is subsequently deposited on the top of the LEP through thermal evaporation technique. The device is further encapsulated with a glass cover lid and epoxy.

A second device, labeled Device 6, is identical to the structure and processing described for Device 5 above except for the following. Device 6 has the following structure: Anode: ITO/HIL: 60 nm ion-replaced PEDOT:PSS/30 nm cross-linked HT interlayer/EML: 75 nm orange LEP/Cathode: 6 nm barium and 200 nm aluminum. The well-defined hole transporting layer (HT) interlayer is a crosslinkable polymeric hole transporting materials spin-coated directly on the top of HIL. After processing, it becomes fully crosslinked and insoluble to the EML solvent. In this example, the deposited HT interlayer thickness is about 30 nm.

The lifetime testing was performed at 85° C. under a multiplexed driving scheme with a duty cycle of 1/64 (mux 64) and frame rate of 100 Hz. The devices were driven at constant current and at initial luminance of 250 nits. As shown in FIG. 4, for the same modified HIL (or with same H⁺ ion replacement), three layer organic stack devices (Device 6) show much better lifetime performance compared to similarly structured two layer organic stack devices at 85° C.

The replacement of H⁺ ions can be performed either after or before deposition over the anode. Ion exchange and neutralization are exemplary of the many possible ways to achieve ion replacement. For neutralization, a base containing the organic or inorganic ions can be added to the conventional available PEDOT:PSS solution. The mixture can be stirred or otherwise caused to react for a period of time. The ion-replaced solution can then be deposited to form the HIL. In ion exchange, a resin or similar material is used to directly strip the H⁺ ion from the PEDOT:PSS solution and then replace it with the organic or inorganic ions of choice such as Na⁺.

As any person of ordinary skill in the art of electronic device fabrication will recognize from the description, figures, and examples that modifications and changes can be made to the embodiments of the invention without departing from the scope of the invention defined by the following claims.

1. An electroluminescent device having a plurality of layers, comprising:
an anode layer;
a hole injection layer disposed over said anode layer, said hole injection layer fabricated using a solution where at least some of acidic ions are replaced by replacement ions;
an emissive layer, said emissive layer capable of emitting light; and
a hole transporting interlayer disposed between said hole injection layer and said emissive layer, said hole transporting interlayer rendered insoluble to the solvent used in fabricating the emissive layer.

2. The device according to claim 1 further comprising:
a cathode layer disposed above said emissive layer.

3. The device according to claim 1 wherein said hole injection layer is fabricated using a conducting polymer solution.

4. The device according to claim 1 wherein the acidic ions being replaced include H⁺ ions.

5. The device according to claim 1 wherein the percentage of acidic ions replaced varies from one to one hundred percent.

6. The device according to claim 1 wherein the percentage of acidic ions replaced varies from twenty to ninty percent.

7. The device according to claim 1 wherein said replacement ions include at least one of organic and inorganic ions.

8. The device according to claim 7 wherein said inorganic ions includes at least one of: Li, Na, Mg, K, Ca, Rb, Sr, Cs, Ba, Al, Mn, Fe, Co, Ni, Cu and Zn.

9. The device according to claim 7 wherein said organic ions includes at least one of: NH₄⁺, N(CH₃)₄⁺, N(C₂H₅)₄)⁺, N(C₃H₈)₄)⁺, N(C₃H₅)₈)⁺, CH₃NH₃⁺, CH₂CH₂NH₃⁺, CH₂CH₂CH₂NH₃⁺, CH₂CH₂CH₂CH₂NH₃⁺, (CH₃)₂NH₂⁺, (CH₃CH₂)₂NH₂⁺, (CH₃CH₂CH₂)₂NH₂⁺, (CH₃)₃NH⁺, (CH₃CH₂)₃NH⁺, and (CH₃CH₂CH2)₃NH⁺.

10. The device according to claim 1 wherein said hole transporting interlayer is chemically cross-linked to render it insoluble to the solvent used in fabricating the emissive layer.

11. The device according to claim 1 wherein said hole transporting interlayer has a polarity to render it insoluble to the solvent used in fabricating the emissive layer.

12. The device according to claim 3 wherein said conducting polymer solution includes poly(3,4-ethylenedioxythiophene)-poly(styrenesulfonic acid).

13. The device according to claim 12 wherein said acidic ions being replaced are H⁺ ions in said poly(3,4-ethylenedioxythiophene)-poly(styrenesulfonic acid).

14. The device according to claim 13 wherein said replacement ions include Na ions.

15. A method for fabricating an organic electroluminescent device, comprising:
fabricating an anode layer;
replacing at least some of the acidic ions in a solution used to fabricate a hole injection layer over said anode layer with replacement ions;
fabricating said hole injection layer over said anode layer with the ion-replaced solution;
fabricating an emissive layer over said hole injection layer;
fabricating a hole transporting interlayer between said emissive layer and said hole injection layer, said hole transporting interlayer; and
rendering said hole transporting interlayer insoluble to the solvent used in fabricating the emissive layer.

16. The method according to claim 15 further comprising:
fabricating a cathode layer over said emissive layer.

17. The method according to claim 15 wherein said replacement ions includes at least one of organic and inorganic ions.

18. The method according to claim 17 wherein said inorganic ions includes at least one of: Li, Na, Mg, K, Ca, Rb, Sr, Cs, Ba, Al, Mn, Fe, Co, Ni, Cu and Zn.

19. The method according to claim 17 wherein said organic ions includes at least one of: NH₄⁺, N(CH₃)₄⁺, N(C₂H₅)₄)⁺, N(C₃H₈)₄)⁺, N(C₃H₅)₈)⁺, CH₃NH₃⁺, CH₂CH₂NH₃⁺, CH₂CH₂CH₂NH₃⁺, CH₂CH₂CH₂CH₂NH₃⁺, (CH₃)₂NH₂⁺, (CH₃CH₂)₂NH₂⁺, (CH₃CH₂CH₂)₂NH₂⁺, (CH₃)₃NH⁺, (CH₃CH₂)₃NH⁺, and (CH₃CH₂CH2)₃NH⁺.

20. The method according to claim 15 wherein the acidic ions being replaced include H⁺ ions.

21. The method according to claim 15 wherein said rendering includes cross-linking said hole transporting interlayer.

22. The method according to claim 15 wherein said hole injection layer is fabricated using a conducting polymer solution.

23. The method according to claim 15 wherein the percentage of acidic ions replaced varies from one to one hundred percent.

24. The method according to claim 15 wherein the percentage of acidic ions replaced varies from twenty to ninty percent.

25. The method according to claim 22 wherein said conducting polymer solution includes poly(3,4-ethylenedioxythiophene)-poly(styrenesulfonic acid).

26. The method according to claim 15 wherein said hole transporting interlayer is caused to have a polarity to render it insoluble to the solvent used in fabricating the emissive layer.

27. The method according to claim 25 wherein said acidic ions being replaced are H⁺ ions in said poly(3,4-ethylenedioxythiophene)-poly(styrenesulfonic acid).

28. The method according to claim 27 wherein said replacement ions include Na ions.
